(19) United States
(12) Patent Application Publication
(10) Pub. No.: US 2007/0158656 A1
(43) Pub. Date: Jul. 12, 2007

(54) Display device and manufacture thereof

(75) Inventors: Woo-jae Lee, Gyeonggi-do (KR); Sung-hoon Yang, Gyeonggi-do (KR)

Correspondence Address: MACPHERSON KWOK CHEN & HEID LLP, 2033 GATEWAY PLACE, SUITE 400, SAN JOSE, CA, 95110, US

(73) Assignee: Samsung Electronics Co., Ltd.

(21) Appl. No.: 11/639,494

(22) Filed: Dec. 14, 2006

(30) Foreign Application Priority Data
Dec. 14, 2005 (KR) 2005-0123419

(51) Int. Cl. H01L 29/04; H01L 21/84

(52) U.S. Cl. 257/72; 438/149; 257/E27.132

(57) ABSTRACT

An LCD includes a thin film display device having a plastic insulating substrate in which lifting of the edge of the thin film is avoided which includes a display region and a non-display region; a gate line assembly formed on the plastic insulating substrate with the use of a shadow mask disposed over the plastic insulating substrate; a gate insulating layer formed on the gate line assembly in the display region; a data line formed on the gate insulating layer and a data pad formed in the non-display region and spaced away from the gate insulating layer; and a passivation layer formed on the data line.

### REFERENCE TO RELATED APPLICATION

This application claims the benefit and priority of Korean Patent Application No. 10-2005-0123419, filed on Dec. 14, 2005, the contents of which are herein incorporated by reference.

### FIELD OF THE INVENTION

The present invention relates to a display device in which an inorganic layer is formed with a shadow mask.

### DESCRIPTION OF THE RELATED ART

Flat panel displays generally include a thin film transistor (TFT) substrate made of a glass insulating material, however plastic insulating substrates that are light and slim are now more often used in place of glass. To improve productivity, TFTs or the like are formed on a plastic mother substrate which is then is cut to form a plurality of TFT substrates.

FIG. 1 illustrates conventional manufacturing of a TFT substrate comprising a plastic insulating substrate. A plastic mother substrate 10 is easily transformed by heat treatment so that it adheres to a dummy glass substrate 20 to be processed. When an inorganic layer is deposited on the plastic mother substrate 10, the inorganic layer is stressed due to poor adhesion to the plastic and the difference in thermal expansion between the plastics and the inorganic layer. Accordingly, the inorganic layer may lift away from the plastic due to the stress.

Conventionally, to decrease the stress on the inorganic layer, the plastic mother substrate 10 is cut into a plurality of sub-substrates 11, as shown in FIG. 1, and then a TFT is formed on each of the sub-substrates 11. However, the thin film may be lifted more than in conventional method since the edge area. which exhibits poor resistance to being lifted, is increased. Further, the required process margin at the edges is 5 mm to 10 mm, and thus an available display area is decreased. Also, the cutting process decreases the adhesive strength between the divided substrates 11 and the dummy glass substrate 20.

### BRIEF SUMMARY OF THE INVENTION

Accordingly, it is an aspect of the present invention to provide a display device in which the thin film does not lift off the substrate. The foregoing and/or other aspects of the present invention may be achieved by providing an LCD including a display device comprising: a plastic insulating substrate having a display region and a non-display region; a gate line assembly formed on the plastic insulating substrate; a gate insulating layer formed on the gate line assembly in the display region; a data line assembly comprising a data line formed on the gate insulating layer and a data pad formed in the non-display region and to be spaced away from the gate insulating layer; and a passivation layer formed on the data line assembly.

According to an exemplary embodiment of the present invention, the gate insulating layer is formed with a shadow mask disposed over the plastic insulating substrate and the shadow mask has an opening corresponding to the display region.

According to an exemplary embodiment of the present invention, the display device further comprises a semiconductor layer and an ohmic contact layer which are disposed on the gate insulating layer in the display region, wherein the gate insulating layer, the semiconductor layer and the ohmic contact layer are sequentially formed with the shadow mask disposed over the plastic insulating substrate.

According to an exemplary embodiment of the present invention, the passivation layer is formed without the shadow mask.

According to an exemplary embodiment of the present invention, the gate line assembly comprises a gate line formed in the display region and a gate pad formed in the non-display region, and the gate pad contacts with the passivation layer.

According to an exemplary embodiment of the present invention, the display device further comprises a counter substrate facing the plastic insulating substrate and a sealant adhering the plastic insulating substrate to the counter substrate, wherein the sealant is spaced away from the gate insulating layer.

According to an exemplary embodiment of the present invention, the display device further comprises a liquid crystal layer disposed between the plastic insulating substrate and the counter substrate.

The foregoing and/or other aspects of the present invention may be achieved by providing an LCD including a display device comprising: a plastic insulating substrate; a gate line assembly formed on the plastic insulating substrate; a gate insulating layer formed on the gate line assembly exposed through an opening of a shadow mask; a data line assembly formed on the gate insulating layer; and a passivation layer formed on the data line assembly.

According to an exemplary embodiment of the present invention, the display device further comprises a semiconductor layer and an ohmic contact layer which are disposed on the gate insulating layer, wherein the gate insulating layer, the semiconductor layer and the ohmic contact layer are sequentially formed through the opening of the shadow mask.

The foregoing and/or other aspects of the present invention may be achieved by providing an LCD including a making method of a display device comprising: forming a gate line assembly on a plastic mother substrate having a plurality of sub-substrate areas which are spaced away from one another; disposing a shadow mask having openings corresponding to the plurality of sub-substrate areas over the plastic mother substrate; forming an inorganic layer on the gate line assembly exposed through the openings; and cutting the plastic mother substrate to obtain a plurality of sub-substrate areas.

According to an exemplary embodiment of the present invention, each of the plurality of sub-substrate areas comprises a display region and a non-display region, and each of the openings corresponds to the display region.

According to an exemplary embodiment of the present invention, the gate line assembly comprises a gate pad formed in the non-display region.

According to an exemplary embodiment of the present invention, the making method of the display device further comprises removing the shadow mask after forming the inorganic layer; and forming a data line assembly on the inorganic layer.

According to an exemplary embodiment of the present invention, the data line assembly comprises a data pad formed in the non-display region.

According to an exemplary embodiment of the present invention, the inorganic layer comprises a gate insulating layer, an amorphous silicon layer and an ohmic contact layer which are sequentially formed.

According to an exemplary embodiment of the present invention, the making method of the display device further comprises forming a passivation layer on the data line assembly.

According to an exemplary embodiment of the present invention, the forming the passivation layer is performed with the shadow mask disposed, and further comprising removing the shadow mask and forming an insulating layer on the passivation layer.

According to an exemplary embodiment of the present invention, the gate insulating layer, the amorphous silicon layer and the ohmic contact layer are sequentially formed by a chemical vapor deposition.

According to an exemplary embodiment of the present invention, the gate insulating layer, the amorphous silicon layer and the ohmic contact layer are formed at 100° C. to 150° C.

According to an exemplary embodiment of the present invention, the plastic mother substrate is adhered to a dummy glass substrate when forming the inorganic layer.

### BRIEF DESCRIPTION OF THE DRAWINGS

The above and other aspects and advantages of the present invention will become apparent and more readily appreciated from the following description taken in conjunction with the accompanying drawings, in which:

FIG. 1 illustrates a conventional method of manufacturing a display device;

FIG. 2 is a perspective view of a display device according to a first embodiment of the present invention;

FIG. 3 is a sectional view, taken along line III-III in FIG. 2;

FIG. 4 is a sectional view, taken along line IV-IV in FIG. 2;

FIGS. 5, 6A-6B, 7, 8A-8B, 9A-9B, 10-10B, 11A-11B and 12A-12B illustrate a method of manufacturing a display device according to the first embodiment of the present invention;

FIGS. 13 and 14 are sectional views of a display device according to a second embodiment of the present invention;

FIGS. 15A and 15B illustrate a method of manufacturing a display device according to the second embodiment of the present invention;

FIGS. 16 and 17 are sectional views of a display device according to a third embodiment of the present invention;

FIGS. 18A and 18B illustrate a method of manufacturing a display device according to the third embodiment of the present invention.

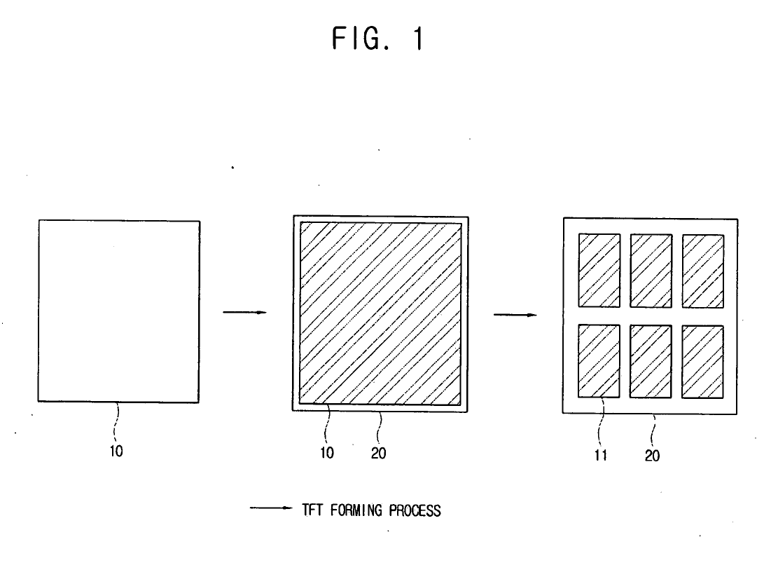

### DETAILED DESCRIPTION OF THE PREFERRED EMBODIMENT

In the following embodiments, a display device will be described with a liquid crystal display (LCD) as an example, but it is not limited to an LCD. Other display devices, such as an organic light emitting diode, an electrophoretic display, and etc., would also be within the scope of these embodiments.

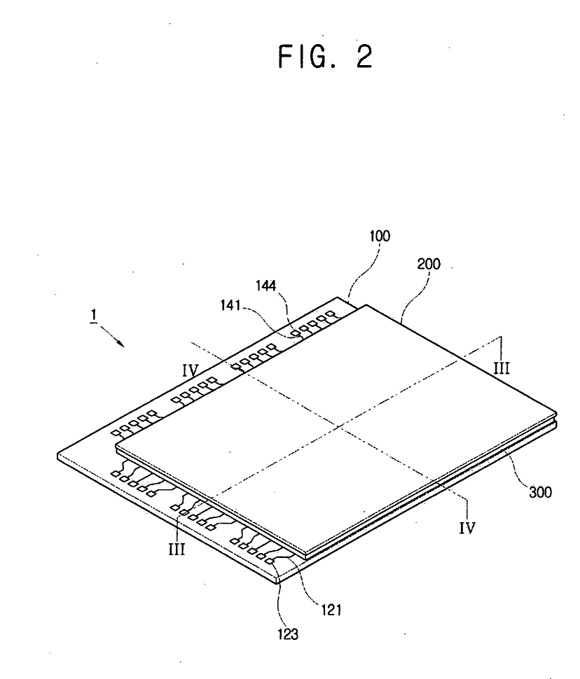

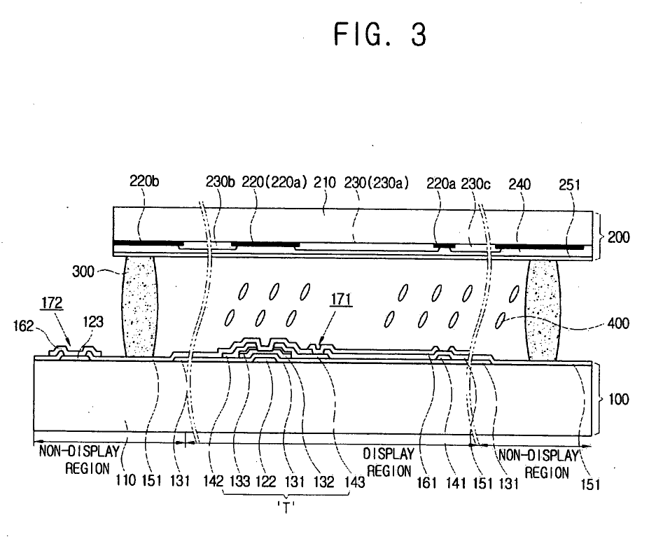

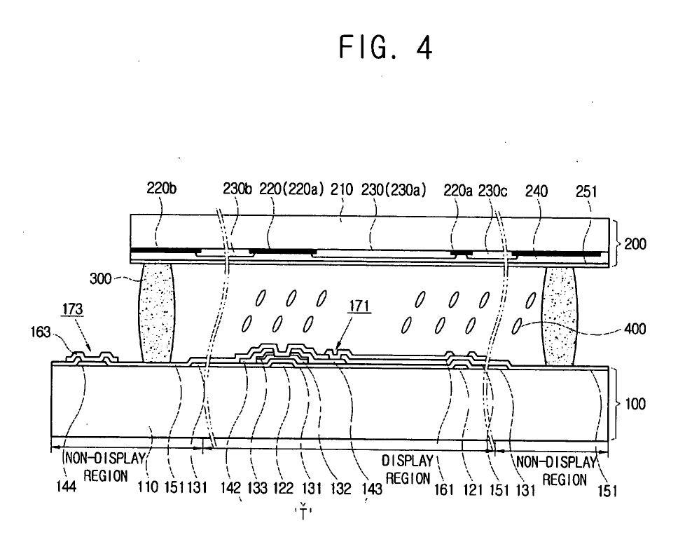

Hereinafter, an LCD panel manufactured according to a first embodiment of the present invention will be described with reference to FIGS. 2 through 4. FIG. 2 is a perspective view of a display device according to a first embodiment of the present invention; FIG. 3 is a sectional view, taken along line III-III in FIG. 2; and FIG. 4 is a sectional view, taken along line IV-IV in FIG. 2.

A display device 1 comprises a first substrate 100 where TFTs T are formed, a second substrate 200 facing the first substrate 100 and where a common electrode 251 is formed, a sealant 300 adhering both substrates 100 and 200 to each other, and a liquid crystal layer 400 disposed between both substrates 100 and 200 and the sealant 300. The first substrate 100 and the second substrate 200 have a rectangular shape, and the first substrate 100 is large as compared with the second substrate 200. The first substrate 100 and the second substrate 200 comprise a display region where the TFTs T are disposed and a non-display region encompassing the display region and where the sealant 300 and pads 123 and 144 are formed.

First, the first substrate 100 is described as follows.

A gate line assembly 121, 122 and 123 is formed on a first plastic insulating substrate 110. The first plastic insulating substrate 110 may comprise polycarbon, polyimide, polyethersulfone (PES), polyarylate (PAR), polyethylenenaphthalate (PEN), polyethylene terephthalate (PET), or the like.

The gate line assembly 121, 122 and 123 comprises a gate line 121 extended transversely, a gate electrode 122 connected to the gate line 121, and a gate pad 123 provided at an end portion of the gate line 121. The gate pad 123 is formed wider than the gate line 121 for connecting with an external circuit.

A gate insulating layer 131 comprises silicon nitride (SiNx) or the like and is formed on the first plastic insulating substrate 110 and the gate line assembly 121, 122 and 123. Most of the gate insulating layer 131 is disposed in the display region. The gate insulating layer 131 is disposed only in a portion of the non-display region adjacent to the display region. Thus, the gate pad 123 formed in the non-display region is spaced away from the gate insulating layer 131.

The gate insulating layer 131 is formed with a shadow mask, so that it is mostly disposed in the display region, which will be described in detail later.

A semiconductor layer 132 comprises amorphous silicon or the like and is formed on the gate insulating layer 131 on the gate electrode 122. Further, an ohmic contact layer 133 comprises n+ hydrogenated amorphous silicon highly doped with n-type dopant and is formed on the semiconductor layer 132. The semiconductor layer 132 is formed of an island shape on the gate electrode 122, and the ohmic contact layer 133 is divided into two parts across the gate electrode 122. Here, the semiconductor layer 132 and the ohmic contact layer 133 are formed with a shadow mask as well as the gate insulating layer 131, which will be described in detail later.

A data line assembly 141, 142, 143 and 144 is formed on the ohmic contact layer 133 and the gate insulating layer 131. The data line assembly 141, 142, 143 and 144 comprises a data line 141 formed lengthwise and crossing the gate line 121 to define a pixel, a source electrode 142 branched from the data line 141 and extended on the ohmic contact layer 133, a drain electrode 143 separated from the source electrode 142 and formed opposite to the source electrode 142 across the gate electrode 122, and a data pad 144 formed at an end portion of the data line 141. The data pad 144 is formed wider than the data line for connecting with an external circuit. Here, the data pad 144 formed in the non-display region directly contacts with the first plastic substrate 110 to be spaced away from the gate insulating layer 131.

A passivation layer 151 comprises a silicon nitride layer, or an a-Si:C:O layer or an a-Si:O:F layer which is deposited by a PECVD method and is formed on the data line assembly 141, 142, 143 and 144 and the semiconductor layer 132 which are not covered with the data line assembly 141, 142, 143 and 144. In the passivaiton layer 151 are formed a contact hole 171 exposing the drain electrode 143, a contact hole 172 exposing the gate pad 123, and a contact hole 173 exposing the data pad 144. The gate insulating layer 131 is removed in the contact hole 171 exposing the drain electrode 143. Here, the gate pad 123 directly contacts with the passivation layer 151, and a portion of the gate pad 123 is overlapped with the passivation layer 151.

A transparent conductive layer 161, 162 and 163 comprising indium tin oxide (ITO) or indium zinc oxide (IZO) is formed on the passivation layer 151. The transparent conductive layer 161, 162 and 163 comprises a pixel electrode 161 connected to the TFT T through the contact hole 171 exposing the drain electrode 143, a first contact member 162 formed in the contact hole 172 exposing the gate pad 123, and a second contact member 163 formed in the contact hole 173 exposing the data pad 144.

Next, the second substrate 200 facing the first substrate 100 is described as follows.

A black matrix 220 is formed on a second plastic insulating substrate 210. The black matrix 220 is formed latticedly and comprises an inner black matrix 220a formed in the display region and an outer black matrix 220b formed in the non-display region. The inner black matrix 220a is formed over the gate line 121, the data line 141 and the TFT T. The inner matrix 220a prevents external light being provided to a channel region of the TFT T, and the outer black matrix 220b is formed to encompass the display region. The outer black matrix 220b is formed wider than the inner black matrix 220a. The black matrix 220 may comprise chrome oxide or an organic material comprising a black pigment.

A color filter 230 is formed between the black matrixes 220. The color filter 230 is formed regularly and comprises sub-layers 230a, 230b and 230c which have different colors.

An overcoat layer 241 is formed on the color filter layer 230. The overcoat layer 241 provides a plane surface.

The common electrode 251 is formed on the overcoat layer 241. The common electrode 251 comprises a transparent conductive material such as ITO or IZO and applies voltage to the liquid crystal layer 400 along with the pixel electrode 161 to control arrangement of liquid crystal molecules within the liquid crystal layer 400.

An arrangement layer (not shown) is formed on the pixel electrode 161 and the common electrode 251. The arrangement layer generally comprises polyimide and is rubbed to arrange the liquid crystal molecules in a regular direction.

The sealant 300 is provided in the circumferences of both substrates 100 and 200. The sealant 300 is formed in the non-display region along the circumference of the display region and comprises ultraviolet hardening resin such as acrylic resin. Also, the sealant 300 may further comprise heat hardening resin such as epoxy resin, an amine-group hardening agent, a filler such as alumina powder and a spacer. Here, the gate insulating layer 131 is not disposed under the sealant 300, thereby not overlapping with each other.

The liquid crystal layer 400 is disposed in a space formed by both substrates 100 and 200 and the sealant 300, and the liquid crystal molecules therein change in their arrangement according to a voltage difference between the pixel electrode 161 and the common electrode 251.

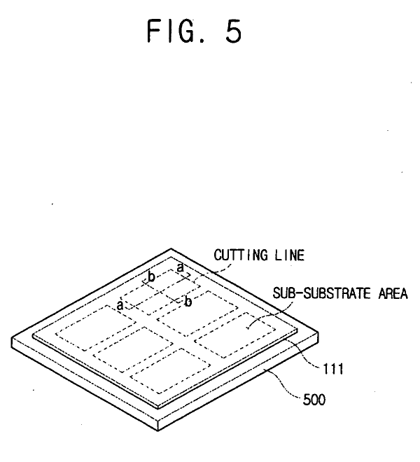

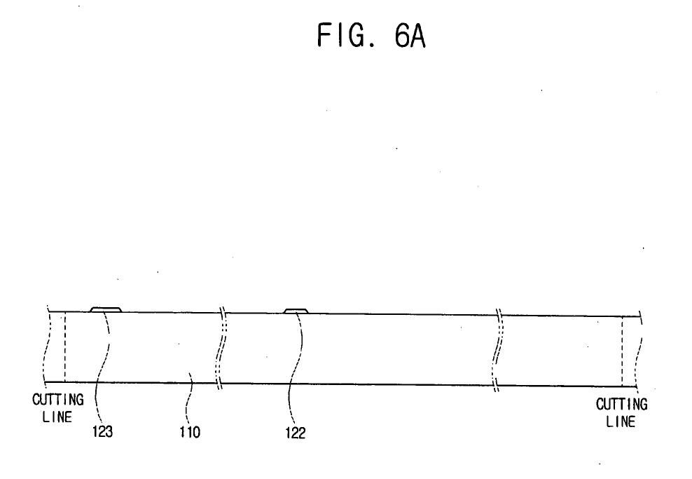

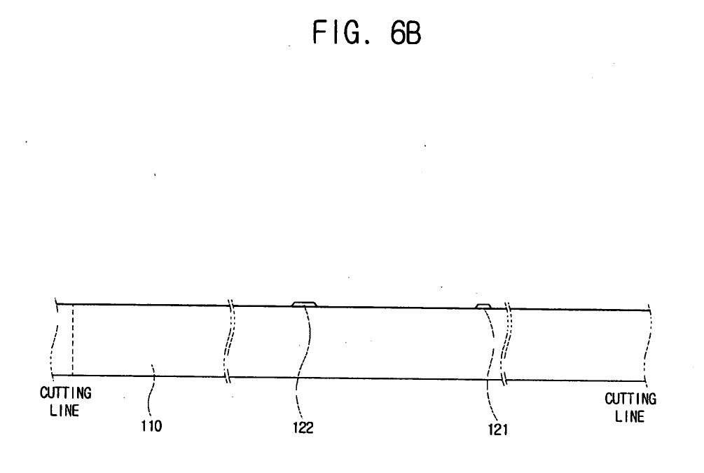

Hereinafter, a method of manufacturing an LCD panel according to the first embodiment of the present invention will be described with reference to FIGS. 5 through 12B. Here, FIGS. 6A, 8A, 9A, 10A, 11A and 12A are sectional views, taken along line a-a in FIG. 5; and FIGS. 6B, 8B, 9B, 10B, 11B and 12B are sectional views, taken along line b-b in FIG. 5.

Referring to FIG. 5, a plastic mother substrate 111 adheres to a dummy glass substrate 500. Six sub-substrates-to-be are spaced away from one another on the plastic mother substrate 111. After the TFTs are formed on the plastic mother substrate 111, the plastic mother substrate 111 is cut along a cutting line to form six sub-substrates. The plastic mother substrate 111 is thin and flexible, so that it is hard to handle. The dummy glass substrate 500 helps the plastic mother substrate 111 to be easily handled.

The dummy glass substrate 500 is formed large both in area and thickness as compared with the plastic mother substrate 111. The plastic mother substrate 111 and the dummy glass substrate 500 may adhere to each other using a temperature-sensitive bonding agent.

Referring to FIGS. 6A and 6B, the gate line assembly 121, 122 and 123 is formed on the plastic mother substrate 111. A gate metal layer is formed across the plastic mother substrate 111 and patterned to form the gate line assembly 121, 122 and 123.

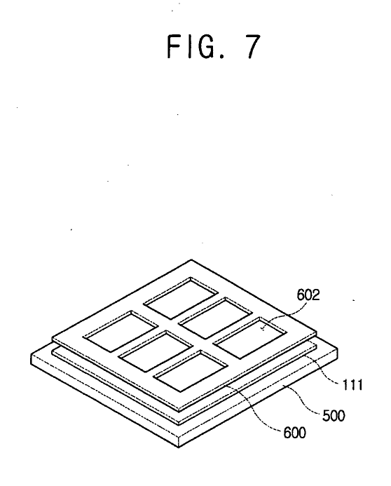

Referring to FIG. 7, a shadow mask 600 is disposed over the plastic mother substrate 111 where the gate line assembly 121, 122 and 123 is formed.

The shadow mask 600 comprises six openings 602 formed therein. The openings 602 have a nearly rectangular shape and their size corresponds to a display region of each sub-substrate area. Thus, the size of the openings 602 is a little smaller than the circumference of the cutting line.

The shadow mask 600 is disposed so the openings 602 correspond to the display regions of the sub-substrate areas. Accordingly, the display regions of the sub-substrate areas are exposed through the openings 602, and the non-display region of the sub-substrate areas and an area between the sub-substrate areas are covered with the shadow mask 600.

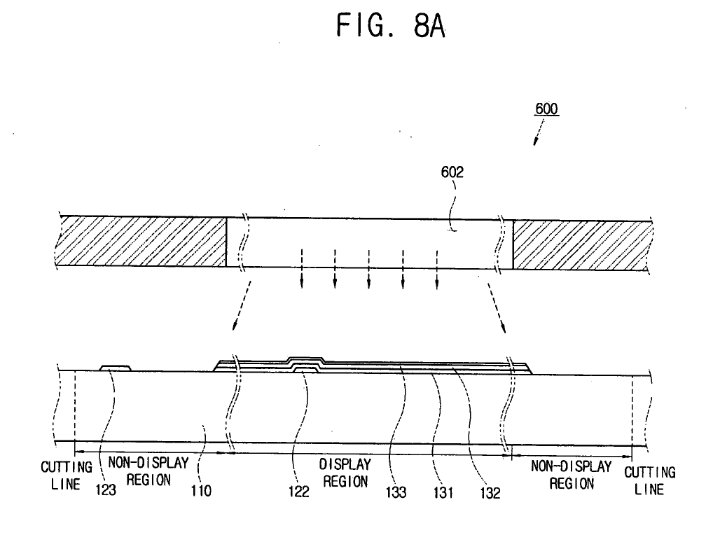

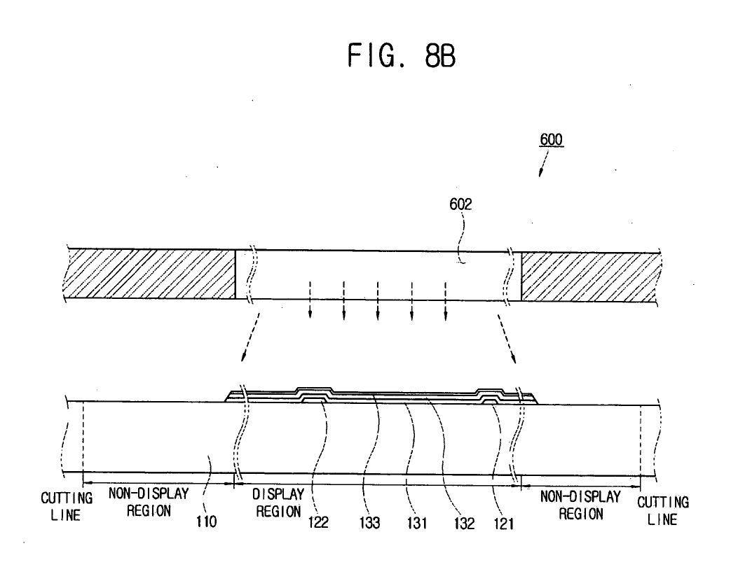

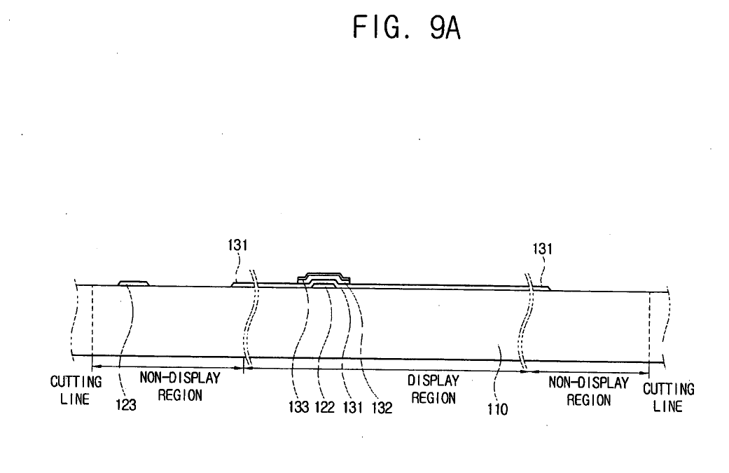

Referring to FIGS. 8A and 8B, triple layers, comprising the gate insulating layer 131 of silicon nitride, the semiconductor layer 132 of amorphous silicon and the ohmic contact layer 133 of a doped amorphous silicon layer, are sequentially deposited, while the shadow mask 600 is disposed over the plastic mother substrate 111. The triple layers are formed by a chemical vapor deposition at 100° C. to 150° C.

Precursor vapor to form the triple layers is provided to the plastic mother substrate 111 through the openings 602 of the shadow mask 600. Since the openings 602 correspond to the display regions, the triple layers are formed mostly in the display regions but are partly formed in the non-display region by diffusion. The triple layers are formed through the openings 602 corresponding to the display regions, and thus the gate insulating layer 131 is not formed on the gate pad 123 disposed in the non-display region.

In making the first substrate 100, the highest temperature is applied when the triple layers are formed, and thus lifting of the thin film is induced. The triple layers in the first embodiment are formed only in the display regions of the sub-substrate areas and not across the plastic mother substrate 111. That is, the triple layers are formed in an island shape on the plastic mother substrate 111. Accordingly, the stress between the triple layers and the plastic mother substrate 111 is decreased, so that lifting of the thin film lift is prevented. The provision of a margin at the edges of the sub-substrates thus is not required, thereby increasing the available area.

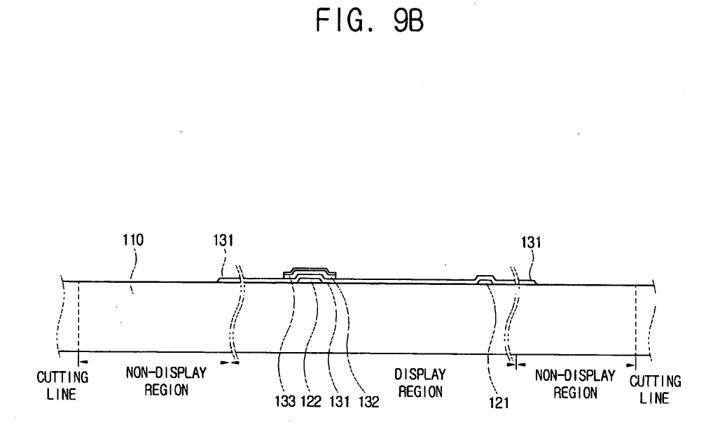

Referring to FIGS. 9A and 9B, the shadow mask 600 is removed, and the semiconductor layer 132 and the ohmic contact layer 133 are etched by photolithography, thereby forming the semiconductor layer 132 and the ohmic contact layer 133 which have an island shape on the gate insulating layer 131 on the gate electrode 122. Through this process, the semiconductor layer 132 and the ohmic contact layer 133 which are formed in a part of the non-display region are removed. On the other hand, the gate insulating layer 131 formed in a part of the non-display region still remains.

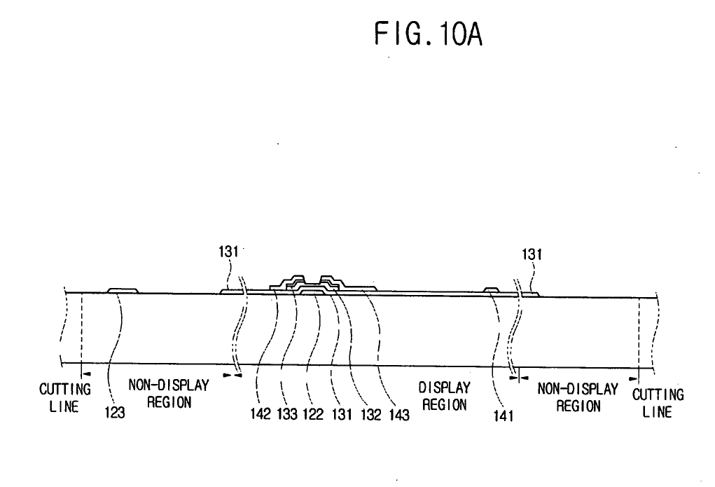

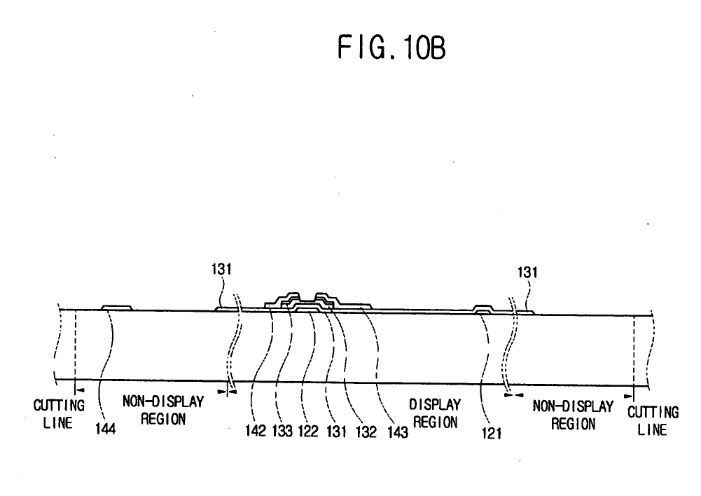

Referring to FIGS. 10A and 10B, the data line 141, the source electrode 142, the drain electrode 143 and the data pad 144 disposed in the non-display region are formed. In this process, the ohmic contact layer 133 not covered with the data line assembly 141, 142, 143 and 144 is etched into two with respect to the gate electrode 122, and the semiconductor layer 132 between the opposite ohmic contact layers 133 is exposed. Then, oxygen plasma is preferably performed to stabilize a surface of the exposed semiconductor layer 132.

A data metal layer is formed across the plastic mother substrate 111 and patterned by photolithography using a mask, thereby forming the data line assembly 141, 142, 143 and 144.

Here, the gate insulating layer 131 is not disposed in an area where the data pad 144 is formed, so that the data pad 144 directly contacts with the plastic mother substrate 111.

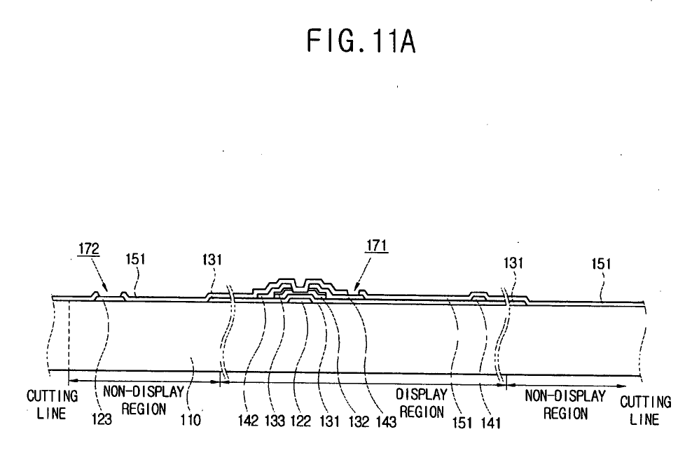

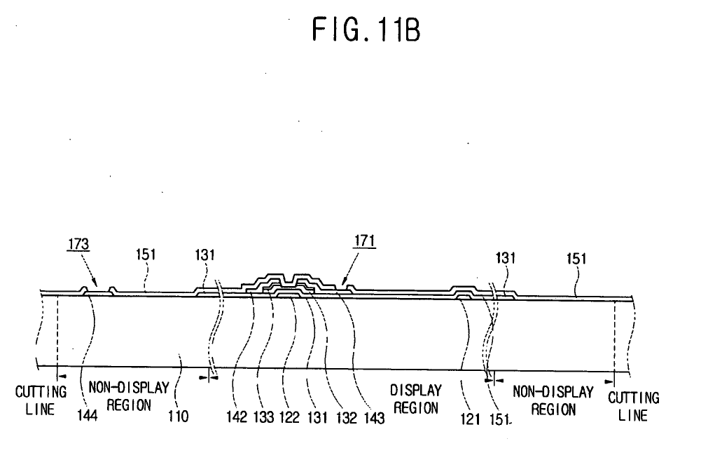

Referring to FIGS. 11A and 11B, the silicon nitride layer, the a-Si:C:O layer or the a-Si:O:F layer is deposited by the CVD and patterned to form the passivation layer 151. The passivation layer 151 is deposited without the shadow mask 600, and thus it is formed across the plastic mother substrate 111. Accordingly, the passivation layer 151 covers the gate pad 123 and the data pad 144, and then is patterned. The passivation layer 151 comprises the contact holes 171, 172 and 173 formed therein to each expose the data electrode 143, the gate pad 123 and the data pad 144.

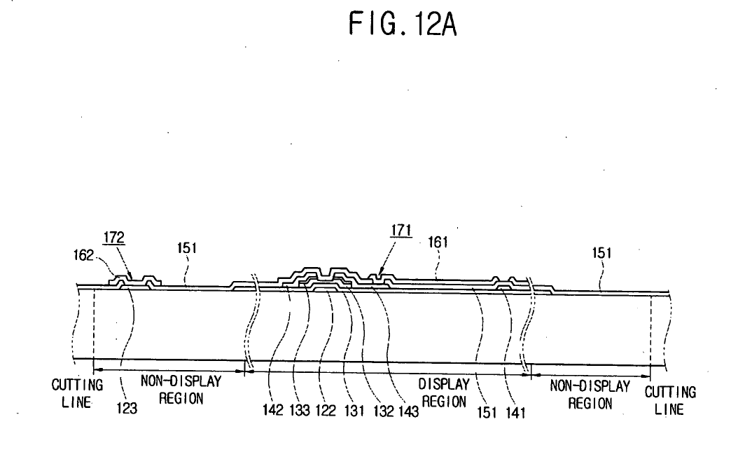

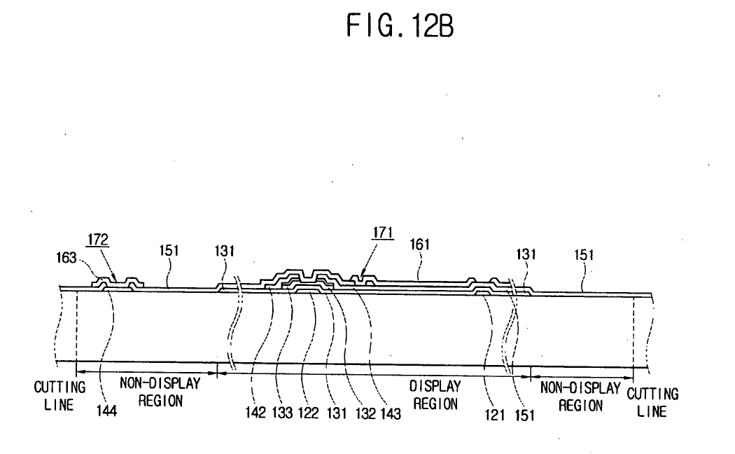

Referring to FIGS. 12A and 12B, a transparent conductive layer is formed and patterned to form the pixel electrode 161, the first contact member 162 and the second contact member 163, thereby completing six first substrates 100 shown in FIGS. 2 through 4. The transparent conductive layer is formed across the plastic mother substrate 111 and patterned. Up to this process, the first substrate 100 is formed with the plastic mother substrate 111.

Thereafter, the second substrate 200 is manufactured using well-known methods. The second substrate 200 may be formed using another plastic mother substrate. Then, the sealant 300 is drawn on one of the first substrate 100 and the second substrate 200. Both substrates 100 and 200 adhere to each other, and the liquid crystal layer 400 is interposed therebetween. The substrates 100 and 200 are cut by a laser or the like, thereby completing the display device 1 shown in FIGS. 2 through 4. The dummy glass substrate 500, not limited thereto, is separated from the first substrate 100 after being cut.

As described above, since the plastic mother substrate 111 is cut after the TFTs are formed in the first embodiment, the edges need not be made wide to avoid lifting of the thin film. Further, the triple layers are not formed across the plastic mother substrate 111 but formed as an island shape on the plastic mother substrate 111, thereby decreasing the stress between the plastic mother substrate 111 and the thin film.

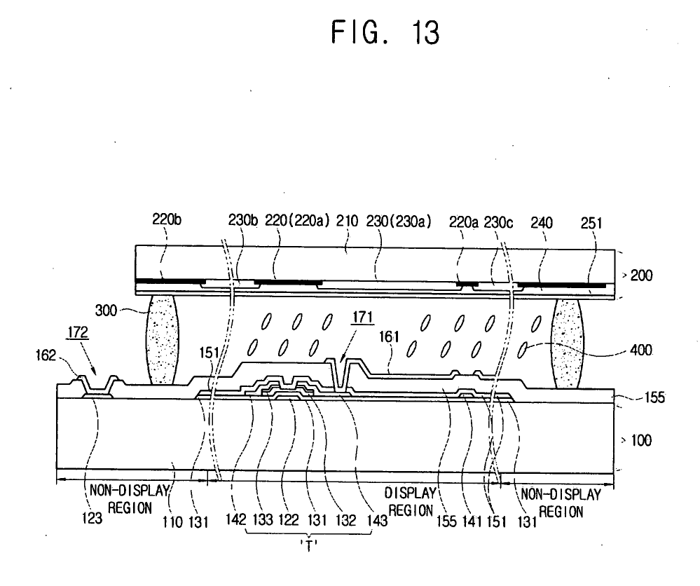

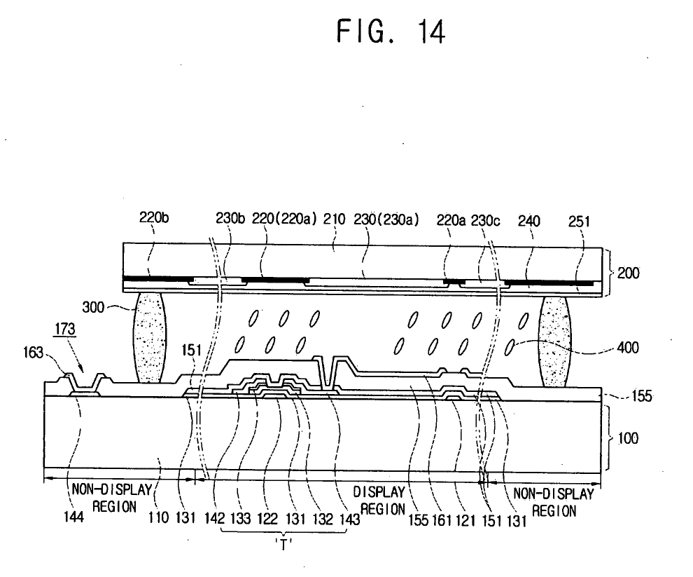

FIGS. 13 and 14 are sectional views of a display device according to a second embodiment of the present invention. FIG. 13 is a sectional view, taken along line III-III in FIG. 2; and FIG. 14 is a sectional view, taken along line IV-IV in FIG. 2.

In the second embodiment, a passivation layer 151 is formed mostly in a display region as well as a gate insulating layer 131. The passivation layer 151 is formed only in a part of a non-display region adjacent to the display region.

Meanwhile, an insulating layer 155 comprising an organic material or the like is formed on the passivation layer 151. Gate pad 123 and a data pad 144 are not overlapped by the passivation layer 151 and directly contact with the insulating layer 155. Sealant 300 is not overlapped by the passivation layer 151 but contacts with the insulating layer 155.

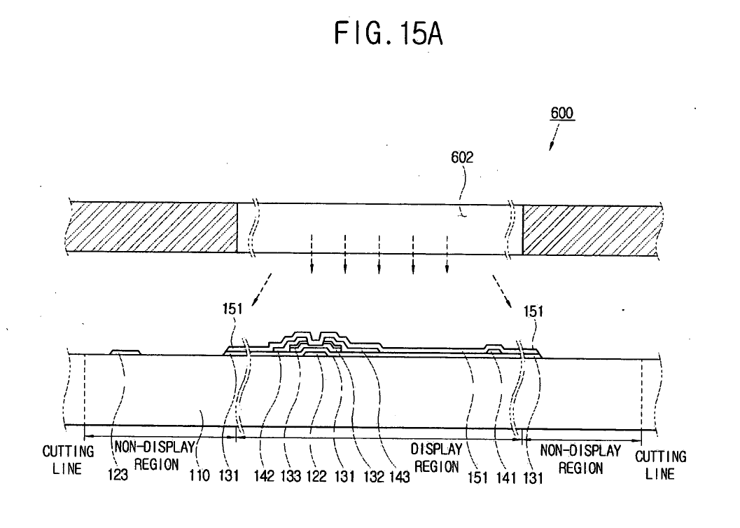

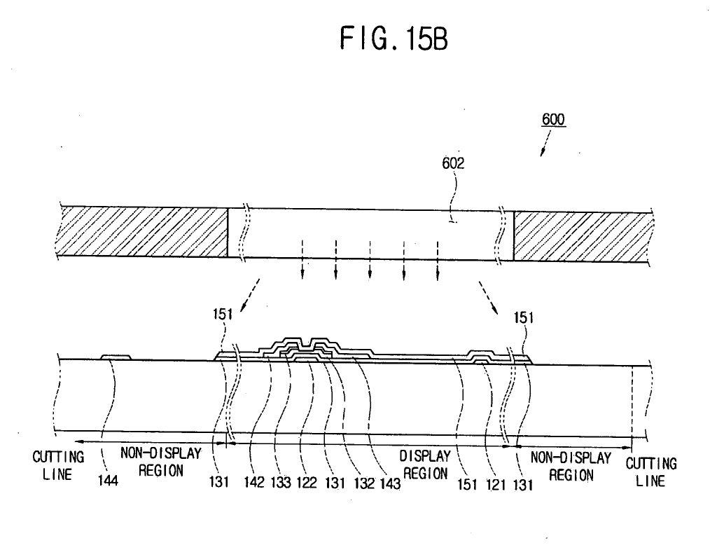

FIGS. 15A and 15B illustrate a method of making a display device according to the second embodiment of the present invention. FIG. 15A is a sectional view, taken along line a-a; and FIG. 15B is a sectional view, taken along line b-b.

FIGS. 15A and 15B show that the passivation layer 151 is formed after the data line assembly 141, 142, 143 and 144 is formed.

Unlike the first embodiment, the passivation layer 151 is formed with a shadow mask 600. The size of an opening 602 of the shadow mask 600 corresponds to the display region, and thus the passivation layer 151 is formed mostly in the display region.

The passivation layer 151 is formed by a CVD as well, but temperature may rise in this process. The passivation layer 151 is formed as an island shape on a plastic mother substrate 111, thereby decreasing the stress between the plastic mother substrate and a thin film.

An organic material is formed across the plastic mother substrate 111 by a slit coating method, a nozzle coating method, a spin coating method or etc. and patterned to form the insulating layer 155 on the passivation layer 151. Temperature does not rise a lot in a coating process, and thus the thin film lift is reduced.

The insulating layer 155 comprises one of a benzocyclobutene (BCB) group, an olefin group, an acrylic resin group, a polyimide group and perfluorocyclobutene (PFCB).

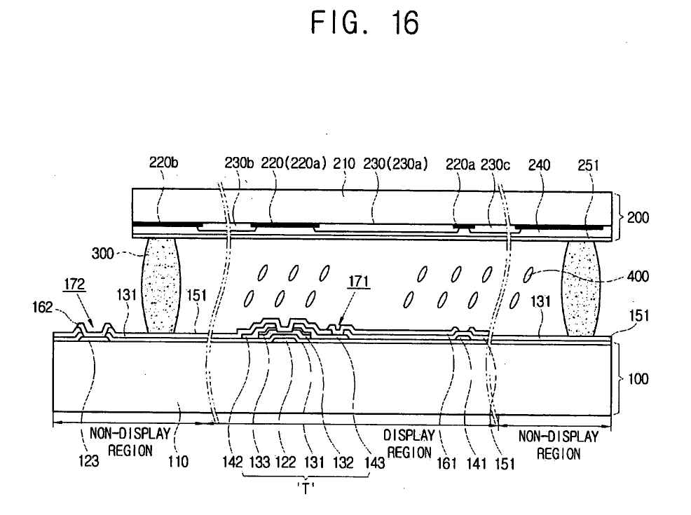

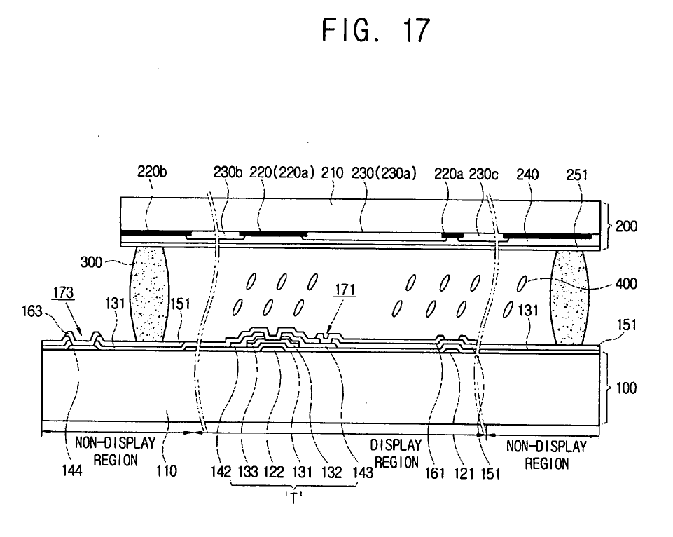

FIGS. 16 and 17 are sectional views of a display device according to a third embodiment of the present invention. FIG. 16 is a sectional view, taken along line III-III in FIG. 2; and FIG. 17 is a sectional view, taken along line IV-IV in FIG. 2.

In a third embodiment, a gate insulating layer 131 is formed in a non-display region as well as in a display region. Accordingly, a gate pad 123 contacts with the gate insulating layer 131, and a data pad 144 is formed on the gate insulating layer 131. A sealant 300 is overlapped with the gate insulating layer 131.

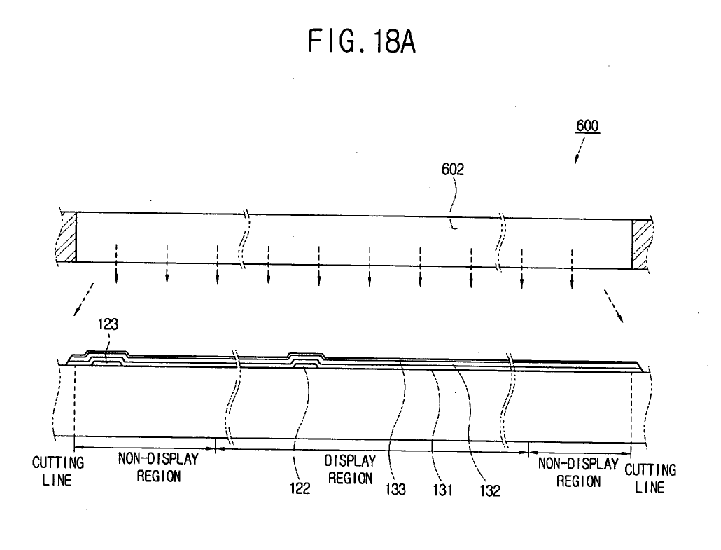

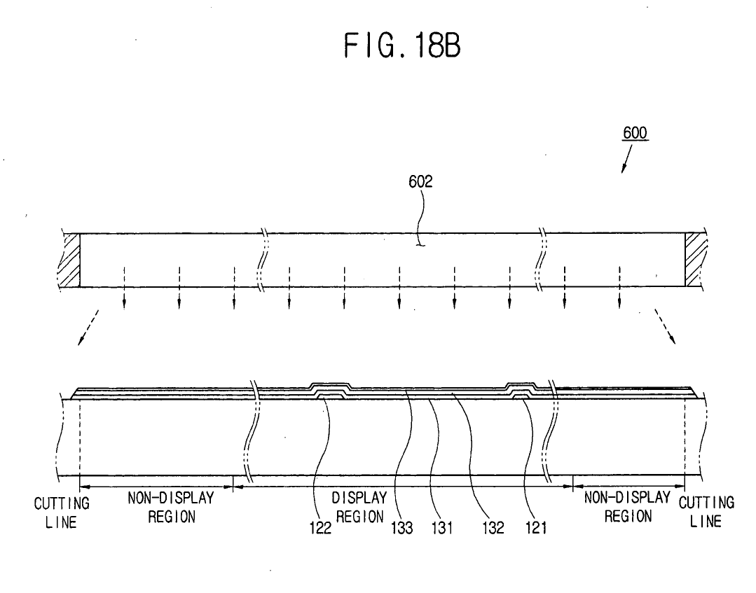

FIGS. 18A and 18B illustrate a method of making a display device according to the third embodiment of the present invention. FIG. 18A is a sectional view, taken along line a-a in FIG. 5; and FIG. 18B is a sectional view, taken along line b-b in FIG. 5.

FIGS. 18A and 18B show that the gate insulating layer 131, a semiconductor layer 132 and an ohmic contact layer 133 are sequentially deposited after a gate line assembly 121, 122 and 123 is formed.

Unlike in the first embodiment, the size of an opening 602 of a shadow mask 600 corresponds to a cutting line. Accordingly, the triple layers are formed both in the display region and in the non-display region inside the cutting line, and partially formed outside the cutting line. Here, the triple layers are deposited in wide area as compared in the first embodiment, but formed as an island shape on a plastic mother substrate 111, thereby decreasing the stress between the plastic mother substrate 111 and a thin film.

Then, a passivation layer 151 is formed with the shadow mask 600 like in the second embodiment, or formed across the plastic mother substrate 111 without the shadow mask 600.

The embodiments described above may be modified variously. For example, a thin film formed with the shadow mask 600 may be modified variously among thin films comprising a line assembly and an inorganic layer. Further, the size of the opening 602 of the shadow mask 600 may be larger than the cutting line, or may be provided in different sizes depending on thin films.

Although a few embodiments of the present invention have been shown and described, it will be appreciated by those skilled in the art that further and other changes may be made in these embodiments without departing from the spirit of the invention.

What is claimed is:

1. A display device comprising:
a plastic insulating substrate having a display region and a non-display region;
a gate line assembly formed on the plastic insulating substrate;
a gate insulating layer formed on the gate line assembly in the display region;
a data line assembly comprising a data line formed on the gate insulating layer and a data pad formed in the non-display region and spaced away from the gate insulating layer; and
a passivation layer formed on the data line assembly.

2. The display device according to claim 1, wherein the gate insulating layer is formed with a shadow mask disposed over the plastic insulating substrate and the shadow mask has an opening corresponding to the display region.

3. The display device according to claim 2, further comprising
a semiconductor layer and an ohmic contact layer which are disposed on the gate insulating layer in the display region, wherein the gate insulating layer, the semiconductor layer and the ohmic contact layer are sequentially formed with the shadow mask disposed over the plastic insulating substrate.

4. The display device according to claim 3, wherein the passivation layer is formed without the shadow mask.

5. The display device according to claim 2, wherein the gate line assembly comprises a gate line formed in the display region and a gate pad formed in the non-display region, and the gate pad contacts with the passivation layer.

6. The display device according to claim 1, further comprising a counter substrate facing the plastic insulating substrate and a sealant adhering the plastic insulating substrate to the counter substrate, wherein the sealant is spaced away from the gate insulating layer.

7. The display device according to claim 6, further comprising a liquid crystal layer disposed between the plastic insulating substrate and the counter substrate.

8. A display device comprising:
a plastic insulating substrate;
a gate line assembly formed on the plastic insulating substrate;
a gate insulating layer formed on the gate line assembly exposed through an opening of a shadow mask;
a data line assembly formed on the gate insulating layer; and
a passivation layer formed on the data line assembly.

9. The display device according to claim 8, further comprising a semiconductor layer and an ohmic contact layer which are disposed on the gate insulating layer, wherein the gate insulating layer, the semiconductor layer and the ohmic contact layer are sequentially formed through the opening of the shadow mask.

10. A method of making a display device comprising:
forming a gate line assembly on a plastic mother substrate having a plurality of sub-substrate areas which are spaced away from one another;
disposing a shadow mask having openings corresponding to the plurality of sub-substrate areas over the plastic mother substrate;
forming an inorganic layer on the gate line assembly exposed through the openings; and
cutting the plastic mother substrate to obtain a plurality of sub-substrate areas.

11. The method of claim 10, wherein each of the plurality of sub-substrate areas comprises a display region and a non-display region, and each of the openings corresponds to the display region.

12. The of claim 11, wherein the gate line assembly comprises a gate pad formed in the non-display region.

13. The method of claim 11, further comprising removing the shadow mask after forming the inorganic layer; and forming a data line assembly on the inorganic layer.

14. The method of claim 13, wherein the data line assembly comprises a data pad formed in the non-display region.

15. The method of claim 10, wherein the inorganic layer comprises a gate insulating layer, an amorphous silicon layer and an ohmic contact layer which are sequentially formed.

16. The method of claim 15, further comprising forming a passivation layer on the data line assembly.

17. The method of claim 16, wherein forming of the passivation layer is performed with the shadow mask, and further comprising removing the shadow mask and forming an insulating layer on the passivation layer.

18. The method of claim 15, wherein the gate insulating layer, the amorphous silicon layer and the ohmic contact layer are sequentially formed by a chemical vapor deposition.

19. The g method of claim 15, wherein the gate insulating layer, the amorphous silicon layer and the ohmic contact layer are formed at 10° C. to 150° C.

20. The method of claim 10, wherein the plastic mother substrate is adhered to a dummy glass substrate when forming the inorganic layer.
